(19) United States
(12) Patent Application Publication
(10) Pub. No.: US 2014/0125313 A1
(43) Pub. Date: May 8, 2014

(54) ELECTRICAL MEASUREMENT APPARATUS HAVING A DETECTOR PROVIDING AN IDENTIFICATION SIGNAL AND CORRESPONDING METHOD

(71) Applicants: Ian Sykes, Bradford (GB); Paul Clay, Bradford (GB); Julia Szajdzicka, Bradford (GB)

(72) Inventors: Ian Sykes, Bradford (GB); Paul Clay, Bradford (GB); Julia Szajdzicka, Bradford (GB)

(21) Appl. No.: 14/113,224

(22) PCT Filed: Apr. 26, 2012
(86) PCT No.: PCT/GB2012/050914

§ 371 Date: Dec. 13, 2013

(30) Foreign Application Priority Data
Apr. 27, 2011 (GB) 1106993.7

(51) Int. Cl. G01R 19/00

(52) U.S. Cl. CPC G01R 19/0092
USPC 324/76.11

(57) ABSTRACT

A three-phase toroidal current transducer comprises a cuboid detector body 12, having three cylindrical passages 14 each for receiving a single-phase cable of a three-phase load (not shown). Each of the three passages 14 has an embedded toroidal winding (not shown) which is used to detect a current in the load cable (also not shown). Signals representing the current in each of the three individual load cables are sent to a meter (not shown), which may be located remotely. The signals are transmitted along a multi-core signal cable 16, which has a standard connector 18 for a plug-in connection to the meter. One of the wires in the multi-core signal cable 16 is connected to a component in the transducer 10 that identifies the rating of the transducer, so that the meter can determine this automatically when the signal cable is plugged in.

The present invention relates to an electrical measurement apparatus and method, and is concerned particularly with an electrical measurement apparatus and method suitable for use in an electrical metering system.

In commercial premises particularly, the electricity usage of several devices or appliances, hereinafter referred to generally as “loads”, is often monitored using separate meters for each load. In such cases, in order to derive valuable data about the energy usage of each load it is necessary to collate metered values manually, and subsequently enter the data manually on a computer for processing.

A previously considered example of electricity meter brings together a fixed number of metering units and combines them in a unitary housing, together with a common visual display and processing means to manipulate and present the data collected by the individual metering units. Signal wires are used to carry the measurement signals from current detectors such as current transducers or transformers located locally at each load. The combined multi-meter load is particularly suited to modern premises in which the electrical supply enters the building at a single location, and is controlled from a single control panel.

Modern electronic electricity meters are designed to measure a variety of load types and sizes.

Current inputs to the meters are standardised to accept a specific signal type and value which represents a larger measured value of current at the load. A range of external current transformers or transducers are used to convert the detected “primary” current into a representative “secondary” signal that may be measured by the metering circuit.

For example a meter may accept a 0.333 Vac signal which represents any nominal primary current determined by the selection of an appropriate external current transducer. Typical external transducers may be of a split or toroidal type such as 100 Amp/0.333V or 500 Amp/0.333V.

When a metering system is installed the user must select the most appropriate transformers/transducers for the measured load dependent on the maximum current that the load would draw in normal operation. These devices may be physically located some distance away from the meters themselves. For example the transformers/transducers may be located in a separate switch enclosure or in a different room. Many meters may be installed together and may be connected to different ranges of transformers/transducers.

During commissioning of the metering system the installing engineer must program the individual meters to provide readings that are scaled in proportion to the specific transformers or transducers to which they are respectively connected. This often presents the practical problem of identifying which set of wires is associated with which remotely located transducer/transformer.

To assist with this the installing engineer carefully labels the wires with the load size and type before installing the transformers/transducers. If this stage is forgotten or performed inaccurately it may be necessary to remove the installation and start again.

If mistakes are made during installation or commissioning these may remain undetected for long periods, and indeed may never be picked up. However, such mistakes can be costly. For example if a 200 Amp transducer is connected to a meter which is programmed to scale for a 150 Amp transducer, when 200 Amps is detected by the transducer the secondary signal will provide 0.333 V to the meter. The meter is scaled to assume that 0.333 V is equivalent to 150 Amps so will display readings which are in error by the ratio 150/200 (i.e. a 25% error). This discrepancy may not be obvious to the meter reader, and the power/energy readings accepted may lead to errors in billing and possibly the taking of inappropriate management decisions based on the erroneous data. Larger errors in scaling may be less likely to escape detection.

Preferred embodiments of the present invention aim to address at least some of the aforementioned shortcomings in the prior systems.

The present invention is defined in the attached independent claims, to which reference should now be made. Further, preferred features may be found in the sub-claims appended thereto.

According to the present invention there is provided electrical measurement apparatus for measuring an electrical parameter of a device, the apparatus comprising a meter and a detector, wherein the detector is arranged to detect the electrical parameter and transmit a measurement signal to the meter, which signal is representative of the detected electrical parameter, and wherein the detector is arranged to provide to the meter an identification signal for identifying the detector to the meter.

In a preferred arrangement the identification signal may be derived from a component in the detector or in an electrical connection between the detector and the meter, or a component associated with either.

The identification signal may be derived from the presence and/or value of the component. Preferably the detector comprises a component having a measurable value, which measurable value serves as the identification signal.

The detector may be arranged to communicate with the meter wirelessly. Alternatively, or in addition, the detector may be connected to the meter by wire. In a preferred arrangement the detector comprises a resistive element, the value of which is measured by the meter to determine the identity of the detector.

The meter may comprise identification means, which preferably comprises a circuit, which is arranged in use to receive the identification signal and to use it to identify the detector.

The invention also includes a detector for use in the measurement of an electrical parameter of a device, wherein the detector is arranged to detect the electrical parameter and transmit a measurement signal to a meter, which signal is representative of the detected electrical parameter, and wherein the detector is arranged to provide to a meter an identification signal for identifying the detector to the meter.

The detector may be according to any statement herein.

The electrical parameter to be measured may comprise electrical current and/or power.

The invention also includes a method of measuring an electrical parameter of a device, the method comprising detecting the electrical parameter using a detector, and transmitting a measurement signal to a meter, which signal is representative of the detected electrical parameter, and wherein the method further comprises providing to the meter an identification signal for identifying the detector to the meter.

The method may comprise identifying the detector by detection and/or measurement of a component in or associated with the detector, the presence and/or value of which component serves to identify the detector.

The invention may comprise any combination of the features or limitations referred to herein, except such a combination of features as are mutually exclusive. A preferred embodiment of the present invention will now be described by way of example only, with reference to the accompanying diagrammatic drawings, in which:

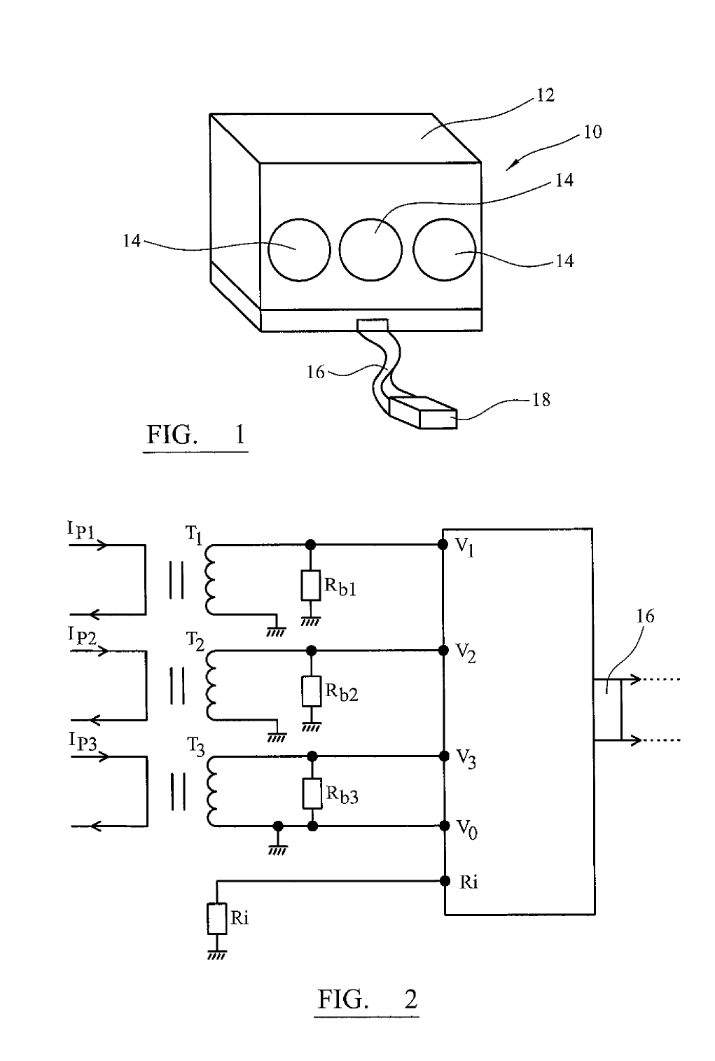

FIG. 1 shows schematically a detector, in the form of a current transducer, for use in apparatus according to an embodiment of the present invention; and

FIG. 2 is a schematic circuit diagram of the current transducer of FIG. 1.

Turning to FIG. 1, there is shown, generally at 10, a three-phase toroidal current transducer comprising a cuboid detector body 12, having three cylindrical passages 14 each for receiving a single-phase cable of a three-phase load (not shown). Each of the three passages 14 has an embedded toroidal winding (not shown) which is used to detect a current in the load cable (also not shown). Signals representing the current in each of the three individual load cables are sent to a meter (not shown), which may be located remotely. The signals are transmitted along a multi-core signal cable 16, which has a standard connector 18 for a plug-in connection to the meter.

As will be described below, one of the wires in the multi-core signal cable 16 is connected to a component in the transducer 10 that identifies the rating of the transducer, so that the meter can determine this automatically when the signal cable is plugged in.

FIG. 2 shows the circuit of the transducer 10. The three currents in the three single-phase load cables are represented by I1, I2 and I3, and the three toroidal windings are represented by T1, T2 and T3. In each case a burden resistor, respectively Rb1, Rb2 and Rb3 is connected between ground and a signal line to produce voltage signals V1, V2 and V3 for supply via cable 16 to the meter. Other wires in the cable 16 include a ground connection V0 and a connection to an identification resistor Ri, itself connected to ground.

The value of the identification resistor Ri can be determined by a resistor-detector circuit in the processor in the meter, and this is used to set the rating of the transducer 10 which the meter uses when calculating the current in the load cables. For example, the meter may be programmed to determine that an identification resistor having a value of 2 kΩ means that the transducer is rated at 100 A/0.333V, which means that if a voltage of 0.333V is measured at any of Vi1, Vi2 or Vi3 this represents a current of 100 A in the respective load cable.

Of course the identification component need not be a resistor. With appropriate circuitry the meter could determine the rating of the transducer by detecting the value of a different type of component. However a resistor provides a particularly inexpensive solution.

Furthermore the current detector need not be a transducer, but could for example be a transformer. In such a case the circuit would be different as there would be two voltage identification lines for each of the single-phase currents. Again a simple resistor could be used as the identification component.

The example given above is of a three-phase load measurement, but the invention is equally applicable to a single-phase load, which would require the use of fewer wires in the cable 16.

During a powering up of the meter the resistor-detector circuit in the meter determines the value of the resistor and automatically configures the meter scaling and calibration to suit the transducer connected, without error or ambiguity to save time during commissioning.

The standard connector 18 is easily plugged into the meter, which also saves time during installation and commissioning of the meter system.

Embodiments of the invention aim to add a low cost component to the transducer or set of transducers which is detected by an additional measurement circuit in the meter. A resistor is sufficient for this purpose, and adds negligible cost to the transducer. Resistor values can be accurately measured by the meter to determine which transducer is fitted at the end of the secondary wires.

The accuracy of the resistor detector could be sufficient as to differentiate between many primary scaling factors and, if required, transducer types. An example of how this could work is laid out in the table shown below:

| Resistor | CT Primary Assumed | CT Type Assumed |
|---|---|---|
| 1 kΩ | 50 Amp | Type A (Small Split CT) |
| 1.2 kΩ | | Type B (Medium Slit CT) |
| 1.3 kΩ | | Type C (Large Split CT) |
| 1.4 kΩ | | Type D (Small Ring CT) |
| 1.5 kΩ | | Type E (Large Ring CT) |
| 2 kΩ | 100 Amp | Type A (Small Split CT) |
| 2.2 kΩ | | Type B (Medium Slit CT) |
| 2.3 kΩ | | Type C (Large Split CT) |
| 2.4 kΩ | | Type D (Small Ring CT) |
| 2.5 kΩ | | Type E (Large Ring CT) |
| 2 kΩ | 150 Amp | Type A (Small Split CT) |
| 3.2 kΩ | | Type B (Medium Slit CT) |
| 3.3 kΩ | | Type C (Large Split CT) |
| 3.4 kΩ | | Type D (Small Ring CT) |
| 3.5 kΩ | | Type E (Large Ring CT) |
| 4 kΩ | 200 Amp | Type A (Small Split CT) |
| 4.2 kΩ | | Type B (Medium Slit CT) |
| 4.3 kΩ | | Type C (Large Split CT) |
| 4.4 kΩ | | Type D (Small Ring CT) |
| 4.5 kΩ | | Type E (Large Ring CT) |
| 5 kΩ | 300 Amp | Type A (Small Split CT) |
| 5.2 kΩ | | Type B (Medium Slit CT) |
| 5.3 kΩ | | Type C (Large Split CT) |
| 5.4 kΩ | | Type D (Small Ring CT) |
| 5.5 kΩ | | Type E (Large Ring CT) |

Whilst endeavouring in the foregoing specification to draw attention to those features of the invention believed to be of particular importance, it should be understood that the applicant claims protection in respect of any patentable feature or combination of features referred to herein, and/or shown in the drawings, whether or not particular emphasis has been placed thereon.

1. Electrical measurement apparatus for measuring an electrical parameter of a device, the apparatus comprising a meter and a detector, wherein the detector is arranged to detect the electrical parameter and transmit a measurement signal to the meter, which signal is representative of the detected electrical parameter, and wherein the detector is arranged to provide to the meter an identification signal for identifying the detector to the meter.

2. Electrical measurement apparatus according to claim 1, wherein the identification signal is derived from a component in the detector or in an electrical connection between the detector and the meter, or associated with either.

3. Electrical measurement apparatus according to claim 2, wherein the identification signal is derived from the presence and/or value of the component.

4. Electrical measurement apparatus according to claim 1 wherein the detector comprises a component having a measurable value, which measurable value serves as the identification signal.

5. Electrical measurement apparatus according to claim 1, wherein the detector is arranged to communicate with the meter wirelessly.

6. Electrical measurement apparatus according to claim 1, wherein the detector may be connected to the meter by wire.

7. Electrical measurement apparatus according to claim 1, wherein the detector comprises a resistive element, the value of which is measured by the meter to determine the identity of the detector.

8. Electrical measurement apparatus according to claim 1, wherein the meter comprises identification means, which comprises a circuit arranged in use to receive the identification signal and to use it to identify the detector.

9. A detector for use in the measurement of an electrical parameter of a device, wherein the detector is arranged to detect the electrical parameter and transmit a measurement signal to a meter, which signal is representative of the detected electrical parameter, and wherein the detector is arranged to provide to a meter an identification signal for identifying the detector to the meter.

10. A method of measuring an electrical parameter of a device, the method comprising detecting the electrical parameter using a detector, and transmitting a measurement signal to a meter, which signal is representative of the detected electrical parameter, and wherein the method further comprises providing to the meter an identification signal for identifying the detector to the meter.

11. A method according to claim 10, comprising identifying the detector by detection and/or measurement of a component in or associated with the detector, the presence and/or value of which component serves as the identification signal.
